(19) United States
(12) Patent Application Publication
(10) Pub. No.: US 2025/0174528 A1
(43) Pub. Date: May 29, 2025

(54) Methods of packaging high voltage and high current power devices

(71) Applicant: BOARD OF REGENTS, THE UNIVERSITY OF TEXAS SYSTEM, Austin, TX (US)

(72) Inventors: Alex Q. Huang, Austin, TX (US); Junhong Tong, Austin, TX (US)

(21) Appl. No.: 18/929,207

(22) Filed: Oct. 28, 2024

Related U.S. Application Data
(60) Provisional application No. 63/593,740, filed on Oct. 27, 2023.

(51) Int. Cl. H01L 23/495; H01L 23/31; H01L 25/07

(52) U.S. Cl. CPC H01L 23/49568; H01L 23/49541; H01L 25/072; H01L 23/3121

(57) ABSTRACT

An exemplary transistor outline package with a double-sided thermal plate is disclosed for double-sided pattern power electronic devices that employ a 3D double-sided cooling package. The exemplary transistor outline package provides spacer or pillar structures with wire bond-less interconnects from a thermal plate or pin frames can improve package reliability. The transistor outline package with a double-sided thermal plate can be configured as a transistor outline (TO) package or a double-side cooling press-pack TO package for a double-side patterned power device.

### GOVERNMENT'S SUPPORT

This material is based upon work supported by the Naval Air Warfare Center under Contract No. N68335-20-C-0337.

### GOVERNMENT LICENSED RIGHTS

This invention was made with government support under N68335-20-C-0337 awarded by the Naval Air Warfare Center. The government has certain rights in the invention.

### BACKGROUND

Power semiconductor device housing or packaging provides an electric connection to the internal power chips and provides a thermal path for heat generated by the chip. Today's power device packages, such as TO-247, typically have three pins, and the heat is only removed from one side of the package.

Different from traditional three-terminal power devices, four-terminal power devices have multiple electrical pads/patterns on both sides of the chip. Current copper/lead frames in current designs do not directly contact the electric pads on both sides of a die because contact patterns of the die are located on opposite sides of the die. To achieve an electrical connection and double-side cooling package on such a chip, strong and miniature pins are needed for both side contacts to realize the electrical connection simultaneously and to distribute the heat.

In addition, a flat copper frame can exhibit field plate effects in which the electric field generated by the power chip can be stronger at the edge of the die or copper frame. The copper frame that extends across the edge of the device can form a device edge termination that can cause degradation or failure as well as increased leakage current. A thick passivation layer and over-designed edge termination have been used previously to address the issues.

There is a benefit to improving the packaging of devices.

### SUMMARY

An exemplary transistor outline package with a double-sided thermal plate is disclosed for double-sided pattern power electronic devices that employ a three-dimensional double-sided cooling package. The exemplary transistor outline package provides spacer or pillar structures, which are wire bond-less interconnects from the thermal plate or pin frames that can improve package reliability. The plate and frame can be employed with epoxy encapsulation of active components in the device to provide high voltage insulation and additional pattern interconnections on both sides of a power electronic die. Experiments illustrate that the 3D copper frames can achieve ultra-low package resistance and excellent thermal handling capability.

The transistor outline package with a double-sided thermal plate can be further configured as a double-side cooling press-pack transistor outline (TO) package for a double-side patterned power device. The transistor outline package can include a spacer (e.g., molybdenum spacer) to provide multiple pad connections with suitable thermal expansion performance on the double side of the chip.

The exemplary transistor outline package and pressed-pack transistor outline package can be configured to address edge field plate effects by being configured, in some embodiments, with (i) small pin dimensions so that it fits the double side pads on the double-side patterned devices, (ii) low profile that can allow for a low interposer thickness and low parasitic inductance, (iii) sufficiently capable for load bearing and heat removal, and (iv) sufficient cross-sections to carry intended current.

In an aspect, a discrete switch package (e.g., single die inside) is disclosed for a four terminal power device with two terminals on each side of the device, the package including: a semiconductor die (e.g., four terminal bipolar transistor die) having a first side and a second side each having terminals and contact metal pads formed thereon; and a first and second cooling plate members for a double-sided cooling package, each die plate member disposed on a side of the die, the first cooling plate member having (i) a first pin structure extending in a direction parallel to the first side of the die to form a first pin for the switch package and (ii) one or more pillar or spacer structures extending in a direction perpendicular to the first side to electrically and thermally contact corresponding one or more electric pads for a first device electrical terminal located on said first side; and at least one cooling frame member, including a first cooling frame member, for the double-sided cooling package, the first cooling frame member being disposed, in electrical isolation, either proximal to the one or more pillar or spacer structures or in a channel formed between pillar structures of the one or more pillar structures, the first frame member having (i) a second pin structure extending in the direction parallel to the first side to form a second pin for the switch package and (ii) one or more pillar or spacer structures extending in a direction perpendicular to the first side to electrically and thermally contact one or more electric pads for a second circuit terminal located on said first side.

In some embodiments, the device further includes a second cooling frame member for the double-sided cooling package, the second cooling frame member is disposed proximal to the pillar or spacer structures of the first cooling plate member, the first frame member having (i) a pin structure extending in the direction parallel to the die surface to form a third pin for the switch package and (ii) a pillar or spacer structure extending in a direction perpendicular to one of the die surfaces to electrically and thermally contact one or more electric pads on the side of the die.

In some embodiments, the second cooling plate member includes (i) a pin structure extending in a direction parallel to the second side of the die to form a fourth pin for the switch package and (ii) one or more pillar or spacer structures extending in a direction perpendicular to the second side to electrically and thermally contact corresponding one or more electric pads for a second circuit terminal located on said second side.

In some embodiments, the semiconductor die comprises a power semiconductor device having two, three, four, or more terminals (e.g., diode, MOSFET, BJT, thyristor), and these terminals are located on two sides of the die.

In some embodiments, the first pin and the second pin are aligned along a same plane.

In some embodiments, the first pin and the second pin include an offset to be aligned along a same plane co-located with a plane of the electrical patterns of the first side, the second side, or a plane located therebetween (e.g., 3D-ladder structure to limit the device edge electrical field).

In some embodiments, the active space of the device is encapsulated by epoxy or dielectric material.

In some embodiments, the semiconductor die, the first and second cooling plate members, and the at least one cooling frame member collectively form a TO-packaged device.

In some embodiments, the semiconductor die, the first and second cooling plate members, and the at least one cooling frame member collectively form a pressed pack package device, wherein the first and second cooling plate members are externally located to components of the device and include mounting holes to receive mounting connectors and pressure.

In some embodiments, the one or more pillar or spacer structures of the first cooling plate member include one or more Molybdenum spacers.

In some embodiments, the package device is wire-bondless and solderless.

In some embodiments, the first cooling frame member has a U-shape member to electrically contact two or more pads of the electrical terminals and contact metal pads of the die.

In some embodiments, the first and second cooling plate members each have a conductive substrate (e.g., copper plate and frame) having an area at least that of the respective side of the semiconductor die, the first and second cooling plate members each being disposed in parallel and facing the respective side to span over the first pad, the second pad, and the third pad.

In some embodiments, the first cooling frame member has a conductive substrate (e.g., copper frame) disposed in the channel and extending in the first direction to form a third external pin to the semiconductor die, the first cooling frame member including a protrusion that each extends in the second direction, in isolation to the first and second pillar of the first cooling plate member, to form a fifth pillar to contact the third pad.

In another aspect, a multi-die package (e.g., multi-dies inside) is disclosed for two or more semiconductor dies (e.g., four terminal bipolar transistor die), including a first semiconductor die, each of the two or more semiconductor dies having a first side and a second side, each side having electrical patterns formed thereon; and the first semiconductor die comprising: a first and second cooling plate members for a double-sided cooling package each die plate member disposed on a side of the die, the first cooling plate member having (i) a first pin structure extending in a direction parallel to the first side of the die to form a first pin for the switch package and (ii) one or more pillar or spacer structures extending in a direction perpendicular to the first side to electrically and thermally contact corresponding one or more electric pads for a first circuit terminal located on said first side; and at least one cooling frame member, including a first cooling frame member, for the double-sided cooling package, the first cooling frame member being disposed, in electrical isolation, either proximal to the one or more pillar or spacer structures or in a channel formed between pillar structures of the one or more pillar structures, the first frame member having (i) a second pin structure extending in the direction parallel to the first side to form a second pin for the switch package and (ii) one or more pillar or spacer structures extending in a direction perpendicular to the first side to electrically and thermally contact one or more electric pads for a second circuit terminal located on said first side.

In some embodiments, the second semiconductor die includes a first and second cooling plate members for a double-sided cooling package each die plate member disposed on a side of the die, the first cooling plate member having (i) a first pin structure extending in a direction parallel to the first side of the die to form a first pin for the switch package and (ii) one or more pillar or spacer structures extending in a direction perpendicular to the first side to electrically and thermally contact corresponding one or more electric pads for a first circuit terminal located on said first side; and at least one cooling frame member, including a first cooling frame member, for the double-sided cooling package, the first cooling frame member being disposed, in electrical isolation, either proximal to the one or more pillar or spacer structures or in a channel formed between pillar structures of the one or more pillar structures, the first frame member having (i) a second pin structure extending in the direction parallel to the first side to form a second pin for the switch package and (ii) one or more pillar or spacer structures extending in a direction perpendicular to the first side to electrically and thermally contact one or more electric pads for a second circuit terminal located on said first side.

In some embodiments, the switch package device includes an array of four terminal bipolar transistor dies.

### BRIEF DESCRIPTION OF DRAWINGS

The components in the drawings are not necessarily to scale relative to each other. Like reference, numerals designate corresponding parts throughout the several views.

FIG. 1 shows an exemplary transistor outline package with double-sided cooling structures for a double-sided pattern power electronic die in accordance with an illustrative embodiment.

FIGS. 2A and 2B show another exemplary transistor outline package with double-sided cooling structures for a double-sided pattern power electronic die in accordance with another illustrative embodiment.

FIGS. 3A and 3B show example configurations of electrical pads of a semiconductor die to which the exemplary switch package of FIGS. 1 and 4 can be employed.

FIG. 3C shows the cross-sectional view of a hypothetic four terminal power devices which can have the electrical pads shown in FIGS. 3A, 3B.

FIGS. 4A and 4B show an exemplary transistor pressed-pack outline package with double-sided cooling structures for a double-sided pattern power electronic die in accordance with an illustrative embodiment.

FIGS. 5A, 5B, and 5C each show photos of a fabricated transistor outline package device.

FIG. 6A shows the experimental setup for the evaluation of the device of FIGS. 5A-5C.

FIG. 6B shows the experimental setup for the evaluation of the device of FIG. 8A.

FIGS. 7Am 7B, 7C, and 7D show simulated and measured characterizations of the device of FIGS. 5A-5C.

FIG. 8A shows a photo of the fabricated device.

FIGS. 8B, 8B, 8C, 8D, 8E, 8F, and 8G show simulated and measured characterization of the device of FIG. 8A.

### DETAILED DESCRIPTION

It is appreciated that certain features of the disclosure, which are, for clarity, described in the context of separate aspects, can also be provided in combination with a single aspect. Conversely, various features of the disclosure, which are, for brevity, described in the context of a single aspect, can also be provided separately or in any suitable subcombination. Unless defined otherwise, all technical and scientific terms used herein have the same meaning as commonly understood by one of ordinary skill in the art. Methods and materials similar or equivalent to those described herein can be used in the practice or testing of the present disclosure.

Some references, which may include various patents, patent applications, and publications, are cited in a reference list and discussed in the disclosure provided herein. The citation and/or discussion of such references is provided merely to clarify the description of the disclosed technology and is not an admission that any such reference is “prior art” to any aspects of the disclosed technology described herein. In terms of notation, “[n]” corresponds to the nth reference in the list. All references cited and discussed in this specification are incorporated herein by reference in their entirety and to the same extent as if each reference was individually incorporated by reference.

### Example System #1

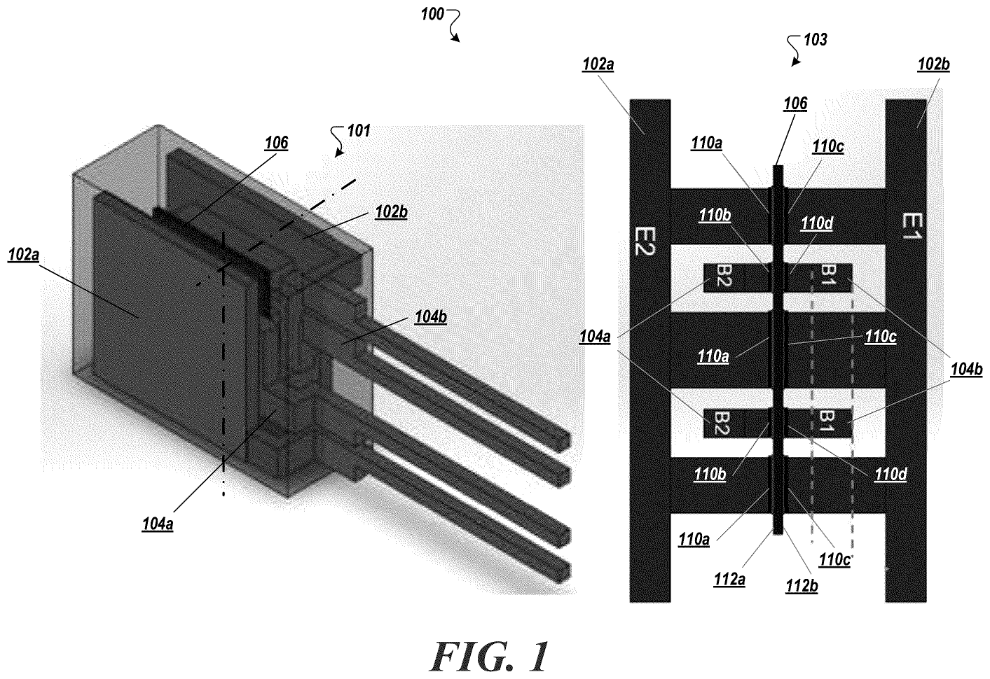

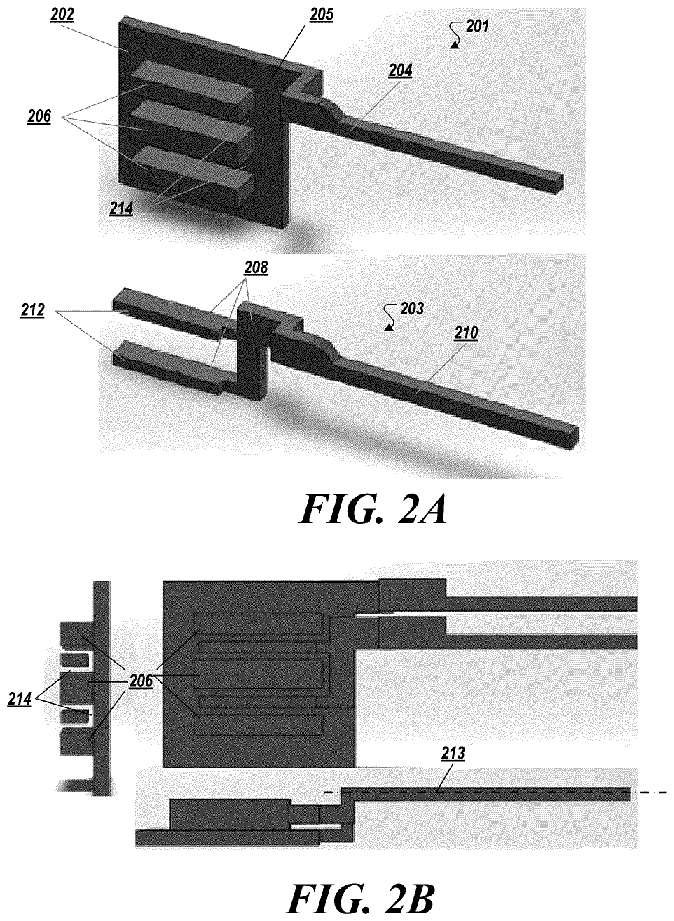

FIGS. 1 and 2 show an exemplary transistor outline package 100 with double-sided cooling structures for a double-sided pattern power electronic die 106 in accordance with an illustrative embodiment. FIG. 1 shows an assembled view of the exemplary transistor outline package 100 (shown as view 101) and a cross-sectional view at plane 103 of the same. In the example shown in FIG. 1, a 4-pin device includes four components for a 4-pin device that includes two thermal plates and frames 102 (shown as 102a, 102b, and referred to as cooling plates) and two frames 104 (shown as 104a, 104b, and referred to here as cooling frames), each isolated from one another to connect to a respective set of pads 110 on the device 106. In the example, the plates 102a, 102b each connect to three pads (110a, 110c), and the frames 104a, 104b each connect to two pads (110b, 110d).

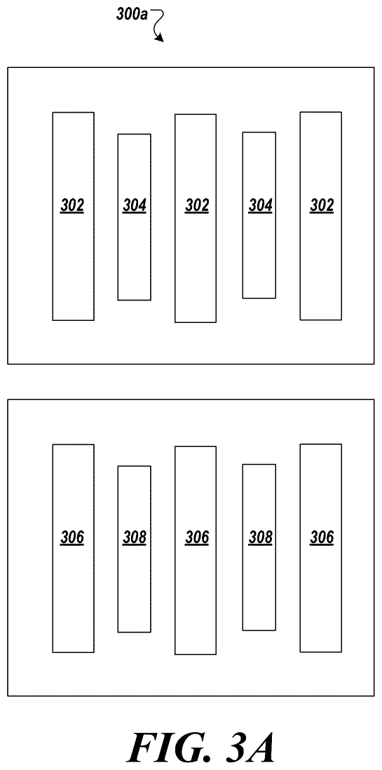

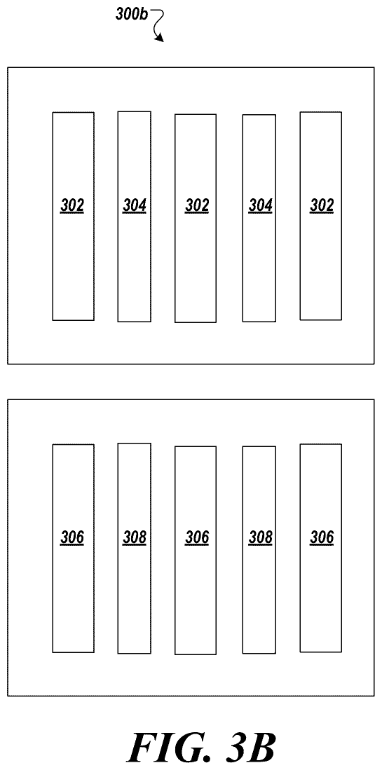

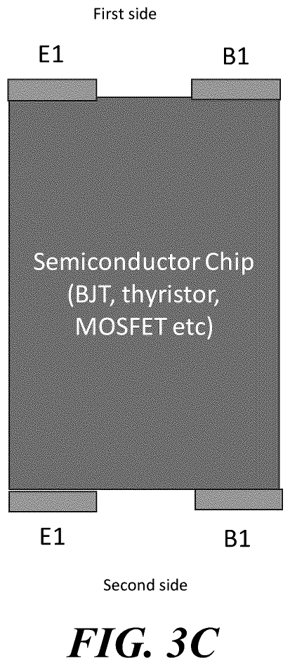

Double-side structure, e.g., four-terminal power transistor, among other devices described herein, has electrical patterns 108a, 108b (see FIGS. 3A, 3B) with multiple electrical pads 110 on both sides (shown as 112a, 112b) of the chip 106. The terms “die” and “chip” are interchangeably used herein. In the example shown in FIG. 1., electrical pads 110 (shown as emitter “E2” 110a and “base “B2” 110b for side 112a and emitter “E1” 110c and base “B1” 110d for side 112b) are terminals for a circuit fabricated on the die 106. An example of a hypothetical four-terminal power transistor is provided in FIG. 3C. FIG. 3A shows an example layout for each side of the die. For BJT devices, the electrical pads 110 include an emitter and base. For FET devices, the electrical pads 110 include a source, gate, and drain. In FIG. 3A, the first side 301 of the device includes 3 pads 302 for the emitter, 2 pads 304 for the base, and the second side 303 also includes three pads 306 for the emitter, and two pads 308 for the base.

The exemplary transistor outline package 100 provides wire bond-less interconnects as pillar structures 112 as protruding from the thermal plate 102 and pin frames 104. The configuration can improve package reliability and can be employed with epoxy encapsulation of active components in the device to provide high voltage insulation and additional pattern interconnections on both sides of a power electronic die. Experiments illustrate that the 3D copper frames can achieve ultra-low package resistance and excellent thermal handling capability.

The cooling plate 102 provides multi-interconnection to one or more pads for a terminal for an electric circuit (e.g., emitter, base, collector, source, gate, drain, among others described or referenced herein). The cooling plate 102 provides pillar structures as 3D-stair or ladder structure that aligns to the metal pads of the due without increasing the device edge electrical field. The discrete structure and lifted-up base provide isolation and multi-pad interconnection. The cooling plate 102 can be soldered, or connected via spacers onto the chip on both sides. A clip aligner can be employed during manufacturing, thus obfuscating requirements for wire bonding. The lack of wire bonding can improve the thermomechanical reliability of the device 100. In some embodiments, to provide the miniaturized and high-resolution structure, wire-cut electrical discharge machining (WEDM) can be used for fabrication. The cooling plate 102 may be formed of copper, copper alloy, lead, lead-alloy, or another suitable thermal and electricity-carrying conductive material.

FIG. 2A shows diagrams 201, 203 of the cooling plate (e.g., 102a, 102b) and the cooling frame (e.g., 104a, 104b) provide electrical connections for 2 pins that connect to pads on one side of the device 106. The cooling plates 102a, 102b and cooling frames 104a, 104b are identical, in this example, to one another and connect to pads on the other side of the device 106, which are also identical. FIG. 2B shows an assembled view of the cooling plate 102 and the cooling frame 104 for one side of the double-sided device. The same assembly is provided in this example for the other side of the device 106. Active spaces of the device, e.g., between the cooling plate and frame, can be encapsulated and adjoined by epoxy or a dielectric material.

In FIG. 2A, diagram 201, the cooling plate 102 includes a plate member 202 with a set of protrusions. The central plate member 102 faces the die (e.g., 106) on one of its sides 205 to conduct heat from that die side and has an exposed side 207, when desired, to conduct heat to the external environment (e.g., a heat sink, environment). The plate member 202 includes a first protrusion 204 as a pin structure that extends in a direction parallel to the surface of the die to form a pin for the switch package. The pin structure 204, in this example, extends from the plate member 102 along a first plane and then is angled to form a second plane to provide an in-line configuration with the other pins that are centered on the die. The plate member 202 includes a second protrusion 206 as one or more pillar structures extend in a direction perpendicular to the surface of the die to electrically and thermally contact corresponding one or more electric pads for a circuit terminal located on that side. The second protrusions 206 form a multi-ladder structure (also can be referred to a multi-stair structure) that is designed and dimensioned to achieve multiple pads' electrical connection and isolation.

In FIG. 2A, diagram 203, the cooling frame 104 includes a connecting member 208, as a set of interconnecting bus structures, with a set of protrusions 210, 212. The central connecting member 208 includes a first protrusion 210 as a pin structure that extends in a direction parallel to the surface of the die to form a pin for the switch package. The pin structure 210, in this example, also extends from the connecting member 208 along a first plane and then is angled to form a second plane (see also FIG. 2B) to provide an in-line configuration (shown via line 213) with the other pins that are centered to the die. The connecting member 208 includes a second protrusion 212 as one or more pillar structures extend in a direction perpendicular to the surface of the die to electrically and thermally contact corresponding one or more electric pads for a circuit terminal located on that side. The second protrusions 206 form multi-ladder structures that are designed and dimensions to achieve multi-pad electrical connection and isolation, e.g., that can be connected (e.g., soldered or otherwise as described herein) to different sides of the base contacts.

FIG. 2B shows an assembled view of the cooling plate 102 and the cooling frame 104 for one side of the double-sided device. As shown in FIG. 2B, the pillar structuress 206 of the cooling frame 104 forms one or more channels 214 to which the pillar structures 212 of the cooling frame 104 can be seated. In the example shown in FIG. 2B, the pillar structures 212 are seated in the channel 214 with pre-defined gaps or distances to the pillar structures 206 of the cooling frame 104.

Example Devices. Table 1 provides an example specification for an example transistor outline package (e.g., 100). The package would be suitable for packaging a double-side patterned discrete power device, such as a chip having emitter and base contacts on both sides of the chip in which Emitter 1 and Basel are on one side, and Emitter 2 and Base 2 are on the other side. Other configurations can be employed, including for layouts of devices described or referenced herein.

TABLE 1

| Parameter | Value | |
|---|---|---|
| Packaging | Discrete | |
| | device package | |
| Voltage Rating | 1200 | V |
| Package Resistance | 0.15 | mΩ |
| Package Inductance | 4.19 | nH (100 kHz) |
| Package Insulation | None-insulated | |
| Terminal Insulation | 3.5 kV (E1 to E2 in air) | |
| Thickness | 6 | mm |
| Package Size (active area) | 20 mm × 15.6 mm | |
| Cooling Function | Double-sided cooling | |
| Thermal Resistance, | 0.175° | C./W |
| junction to case | | |

### Example Double-Sided Device and Layout

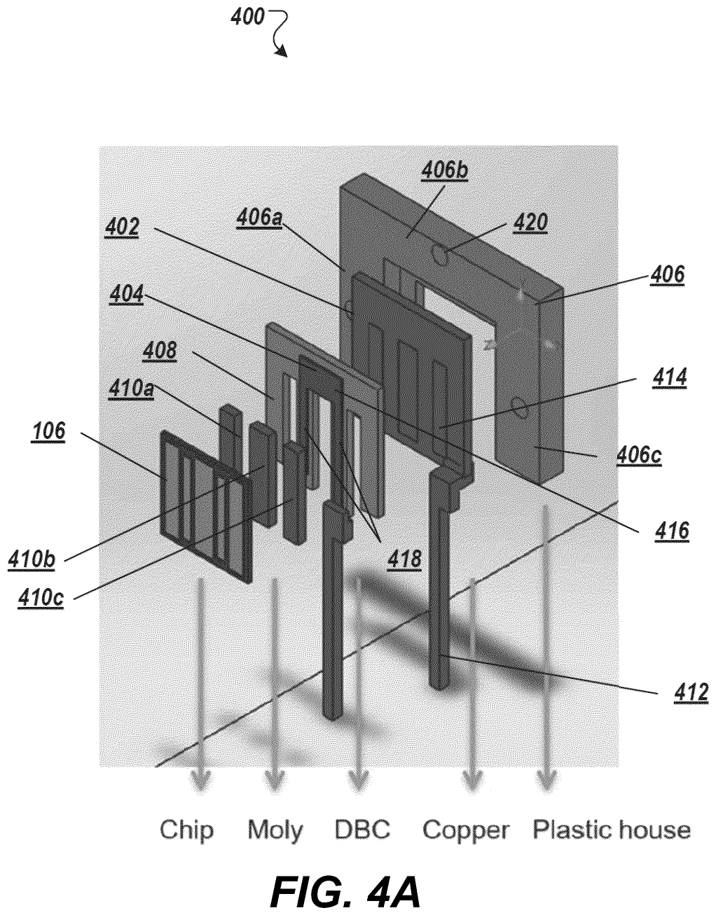

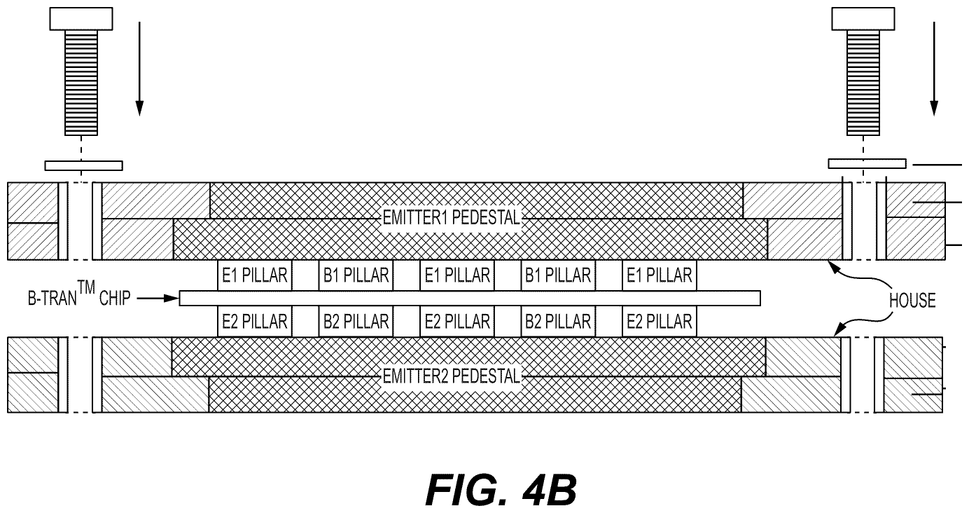

FIGS. 3A and 3B show example configurations of electrical pads of a semiconductor die to which the exemplary switch package of FIGS. 1 and 4 can be employed. FIG. 3C shows the cross-sectional view of a hypothetic four terminal power device, which can have the electrical pads shown in FIGS. 3A, 3B.

### Example System #2

FIGS. 4A and 4B show an exemplary transistor pressed-pack outline package 400 with double-sided cooling structures for a double-sided pattern power electronic die 106 in accordance with an illustrative embodiment. FIG. 4A shows an unassembled internal view of the exemplary transistor outline package 400, and FIG. 4B shows a cross-sectional view of the same. In the example shown in FIG. 4, one side of a 4-pin device is shown that would include two thermal plates and frames 102 (shown as 402 and referred to herein as cooling plate 402) and two frames 104 (shown as 404 and referred to herein as cooling frames 404), each isolated from one another to connect to a respective set of pads 110 on the device 106. In the example, the plates 402 each connect to three pads (110a, 110c), and the frames 404 each connect to two pads (110b, 110d).

The transistor pressed-pack outline package 400 further includes an external housing member 406, direct bonding contact (“DBC”) 408, and spacers 410 (shown as Molybdenum “Moly” spacers 410a, 410b, 410c).

In FIG. 4A, the cooling plate 402 includes a plate member 404 with a set of protrusions. The central plate member 402 faces the die (e.g., 106) on one of its sides to conduct heat from that die side and has an exposed side, when desired, to conduct heat to the external environment (e.g., a heat sink, environment). The plate member 402 includes a first protrusion 406 as a pin structure that extends in a direction parallel to the surface of the die to form a pin for the pressed-pack switch package. The pin structure 412, in this example, extends from the plate member 402 along a first plane and then is angled to form a second plane to provide an in-line configuration with the other pins that are centered on the die. The plate member 402 includes recesses 414 to receive spacers 410 (e.g., Molybdenum spacers) that would extend in a direction perpendicular to the surface of the die to electrically and thermally contact corresponding one or more electric pads for a circuit terminal located on that side.

In FIG. 4A, the cooling frame 404 includes a U-shaped connecting member 416 with an area 418 for contact with the electrical pads of the die 106. The U-shaped connecting member 416 is used for base interconnections as well as for the alignment of the spacer pads. In other embodiments, rather than the U-shaped structure, the cooling frame 404 may be implemented as a bus structure (e.g., 208) as described in relation to FIGS. 1 and 2A-2B.

In the example shown in FIG. 4A, three spacers 410 are employed on each side of the chip that provide interconnectors for the die circuit (e.g., emitter, base, collector, source, gate, drain, among others described or referenced herein). The cooling plate 402 can serve as a substrate base that provides mechanical support and thermal interface.

The housing 406 (e.g., plastic housing) can provide balance pressure on the chip to achieve the desired electric performance. In the example shown in FIG. 4A, the plastic house 406 is shown to include three edge members 406a, 406b, 406c. The edge members 406a, 406b, 406c are recessed to receive and support the cooling plate 402. The edge members 406a, 406b, 406c include mounting holes 420 to receive connection members (e.g., bolts) for the press-pack device 400.

The exemplary transistor pressed-pack outline package 400 can be used in the TO package and can provide balanced pressure distribution (e.g., at 350 psi).

Example Devices. Table 2 provides an example specification for an example transistor pressed-pack outline package (e.g., 400). The package would be suitable for packaging a double-side patterned discrete power device, such as a chip having emitter and base contacts on both sides of the chip in which Emitter 1 and Basel are on one side and Emitter 2 and Base 2 on the other side. Other configurations can be employed, including for layouts of devices described or referenced herein.

TABLE 2

| Parameter | Value | |
|---|---|---|
| Packaging | Discrete | |
| | device package | |
| Device | Double-side | |
| | patterned device | |
| Voltage Rating | 1200 | V |
| Package Resistance | 0.38 | mΩ |
| Package Inductance | 4.19 | nH (1O0 kHz) |
| Package Insulation | None-insulated | |
| E1 to E2 Terminal | 2.5 kV peak non-filling, | |
| Insulation | 7 kV peak with oil filling | |
| Package Size (active area) | 20 mm × 25 mm × 4.5 mm | |
| Cooling Function | Double-sided cooling | |
| Thermal Resistance, | 0.1242° | C./W |
| junction to case | | |

Table 3 provides example physical properties of the transistor pressed-pack outline package (e.g., 400). The comparable thermal properties of AlN and Mo can provide thermal stress balance and increased package reliability. In addition, both the electrical contacts of the spacers and direct bonding contact can provide a balanced thermal conduction path and electrical connections to the plate member 404. The U-shape DBC 408 can align the spacer pads to simplify the assembly process. To reduce the electric field crowding effect, all connectors may be designed to ensure that they do not cross the edge of the chip to increase the package isolation capability of the device 400.

TABLE 3

| | Thermal | CTE | Young's | Poisson |
|---|---|---|---|---|
| | Conductivity | (ppm/ | Modulus | Ratio |
| Material | (W/mK) | ° C.) | (Gpa) | (n.d.) |
| Si | 140 | 2.6 | 169 | 0.361 |
| Copper | 385 | 16.7 | 117 | 0.34 |
| AIN | 170 | 5.3 | 302 | 0.23 |
| Molybdenum | 138 | 5 | 320 | 0.29 |

### Experimental Results and Additional Examples

A study was conducted to develop and evaluate a TO double-side cooling package for the double-side pattern device, including (i) a low-cost 1.2 kV TO double-side cooling package for the double-side pattern device and (ii) a low-cost 1.2 kV TO double-side press-pack cooling package for the double-side pattern device with press-pack configuration.

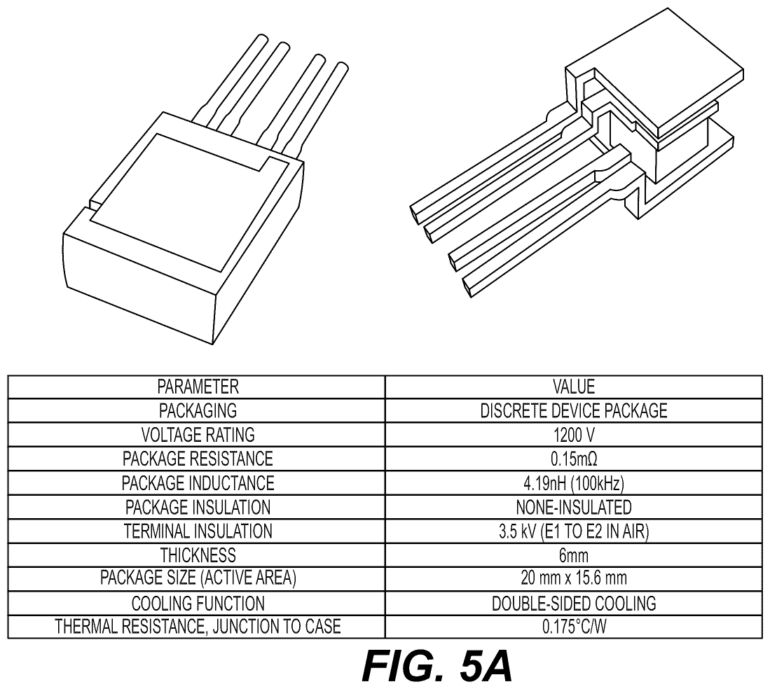

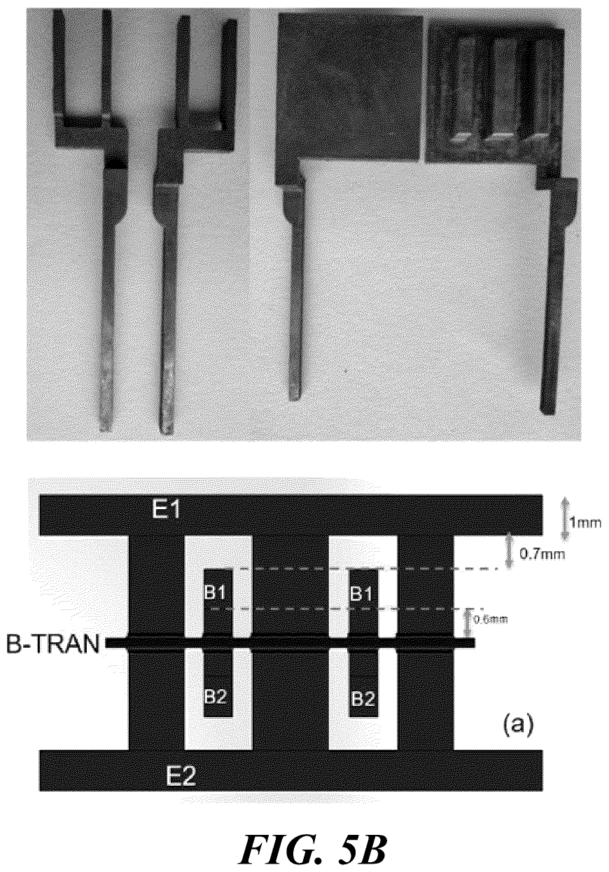

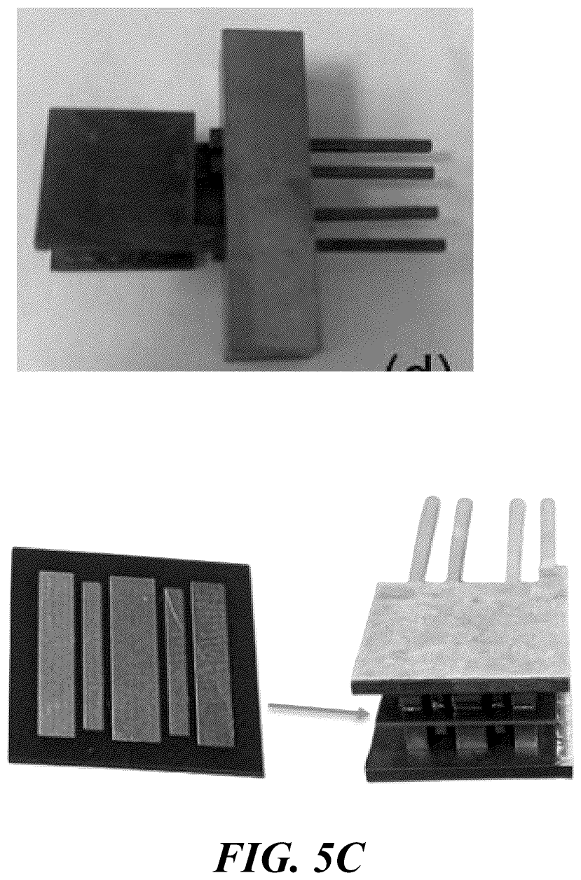

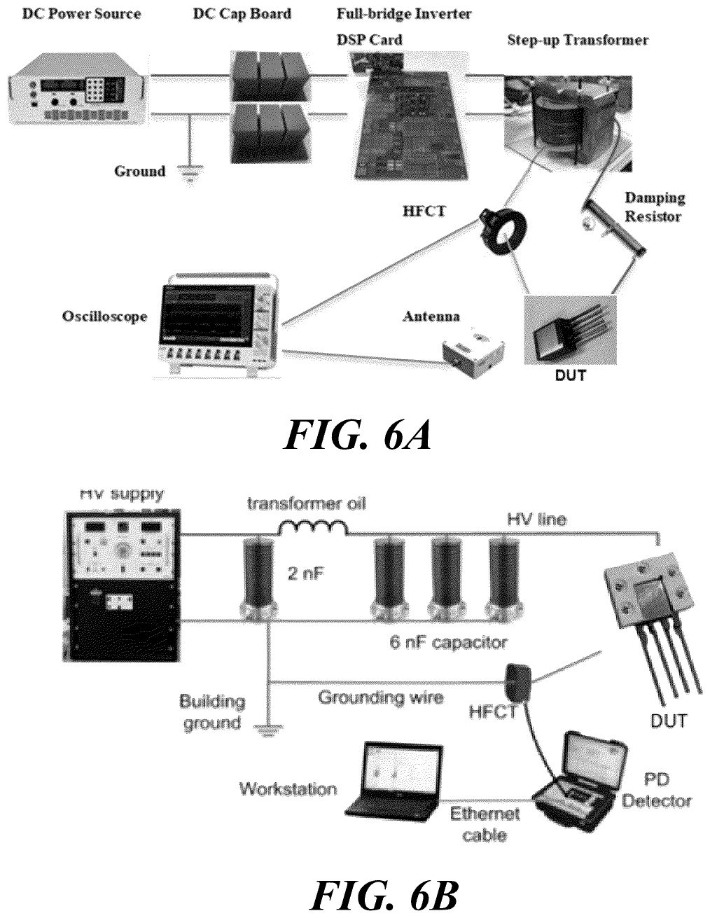

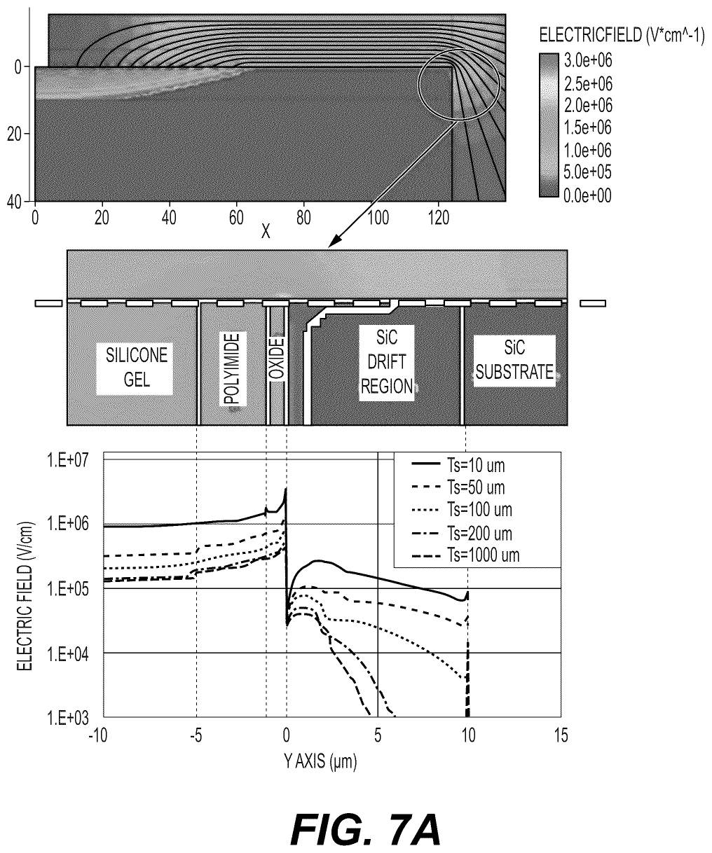

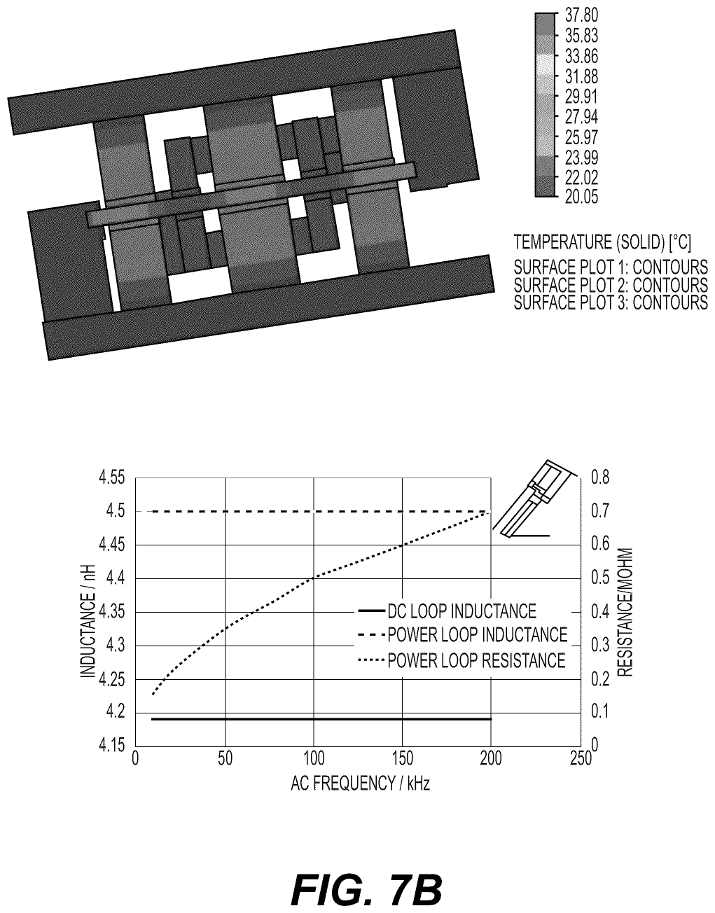

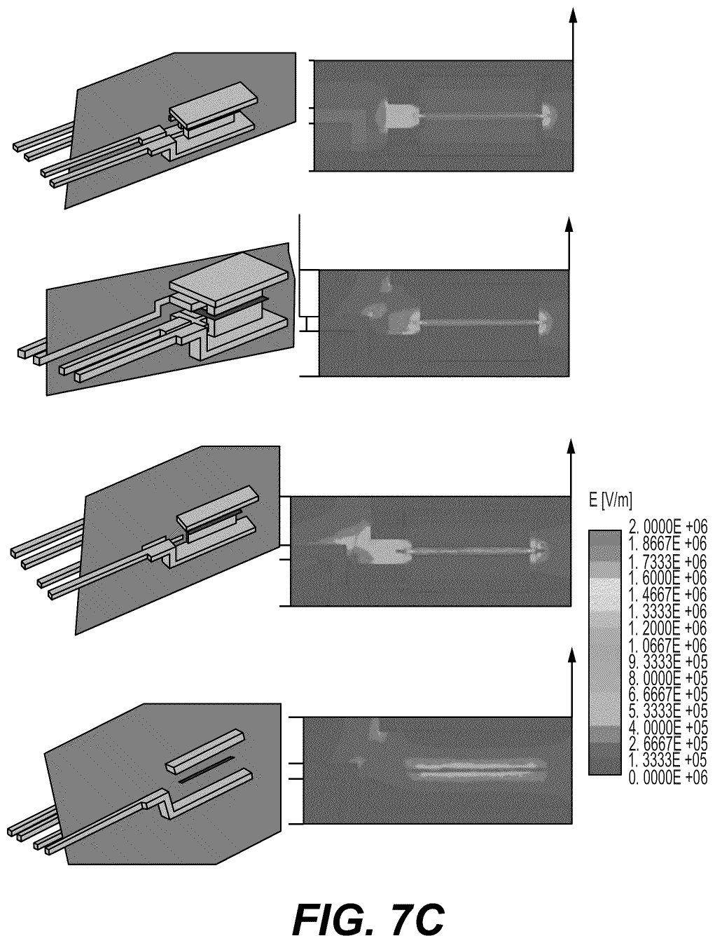

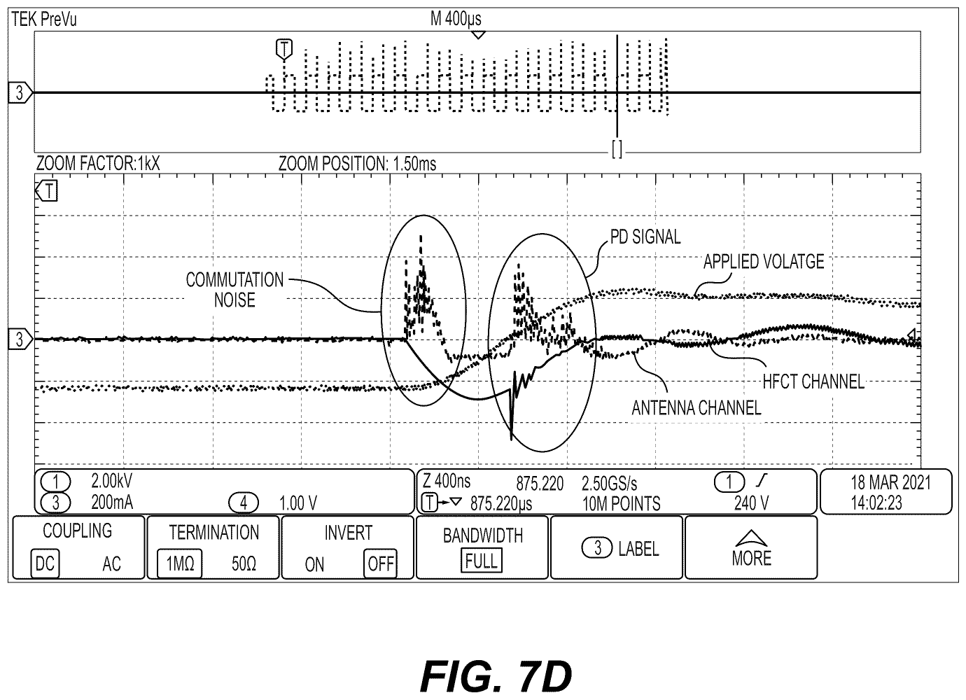

For the TO double-side cooling package, the study fabricated two 3D stair/ladder copper lead frames, described herein, for both multiple pads interconnection and heat sink, one for each side of the chip. The study observed that the double-side cooling configuration reduced the thermal resistance of the packing to less than 0.1775° C./W, reduced the parasitic resistance from the package to 0.15 mΩ, and reduced power loop parasitic inductance to 4.19 nH. The insulation capability was analyzed by simulation and partial discharge (PD) test. Partial discharge inception voltage (PDIV) was observed to be around three times higher than the rated voltage. FIGS. 5A and 5B shows an example fabricated TO double-side cooling package. FIGS. 5A-5C show photos of the fabricated device. FIG. 6A shows the experimental setup for the evaluation of the device. FIGS. 7A-7D show simulated and measured characterizations of the device.

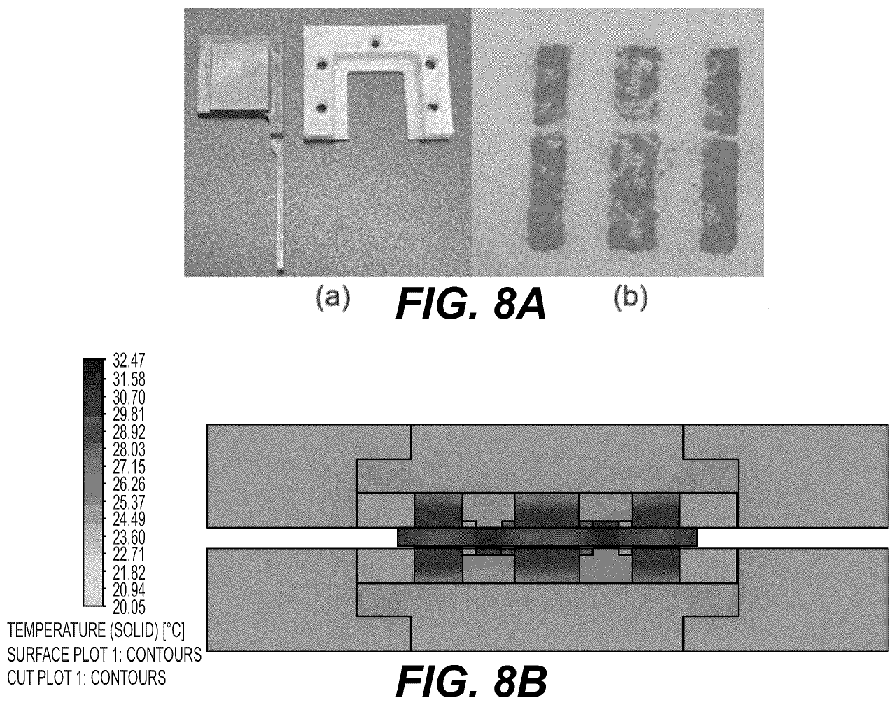

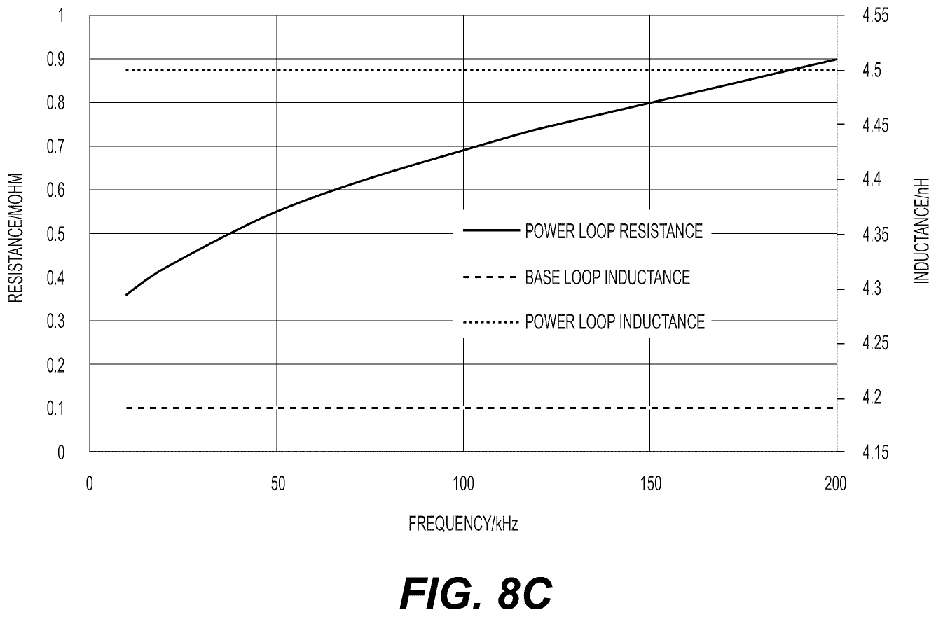

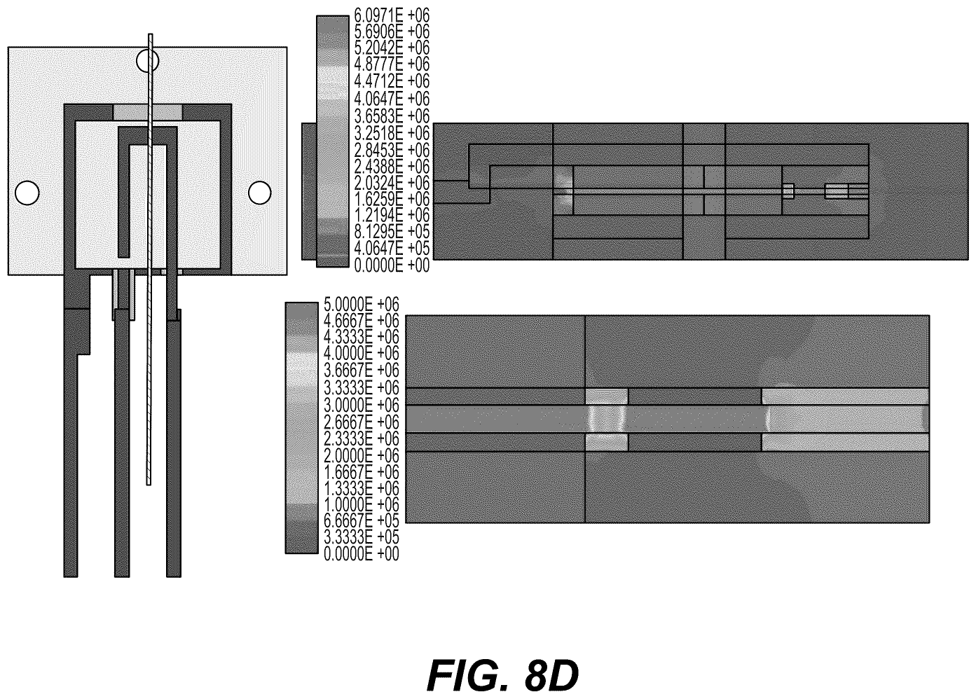

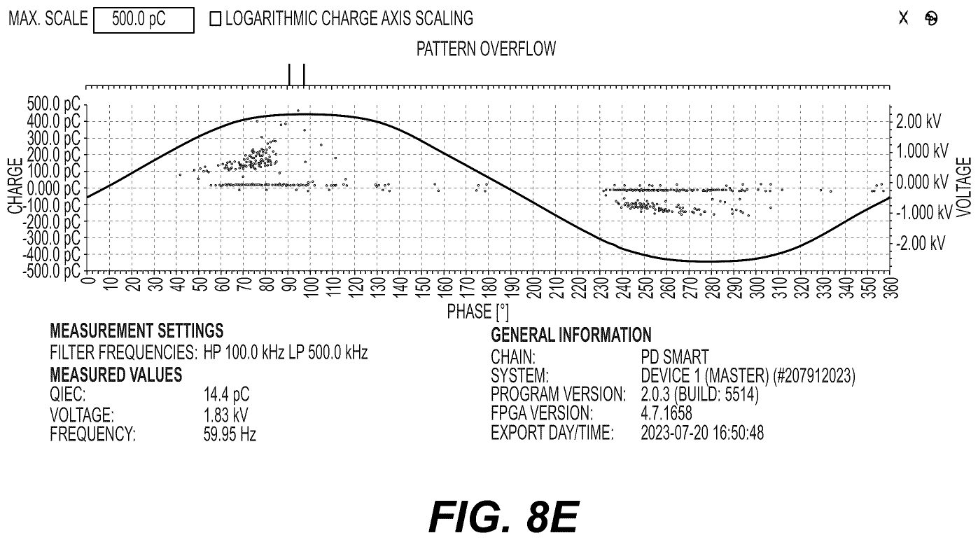

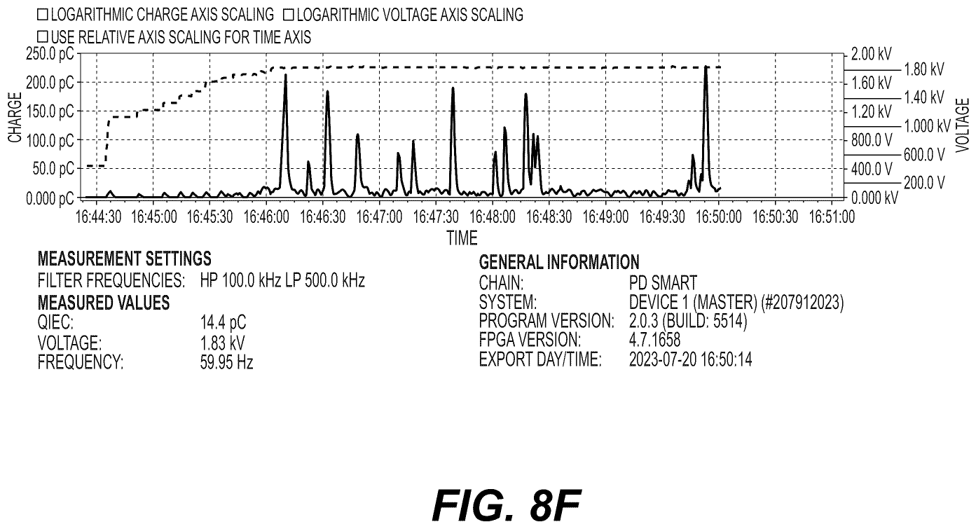

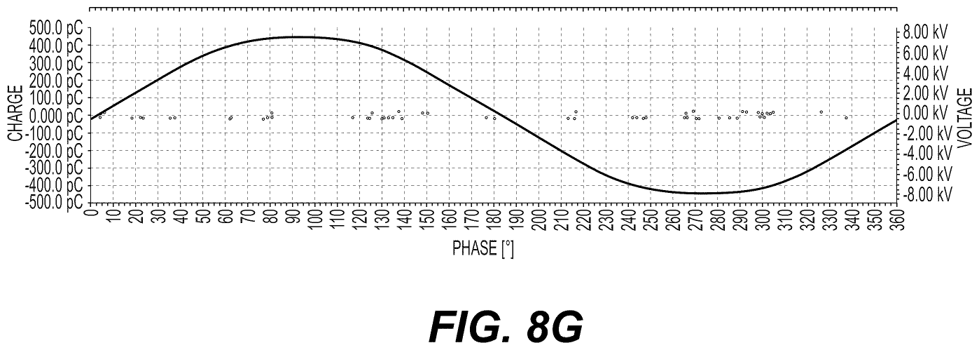

For the TO double-side pressed-pack cooling package, the study fabricated the TO double-side cooling package for the double-side pattern device based on Press-Pack configuration as described in relation to FIG. 4. DBC and Mo spacer connectors were fabricated for multiple pads interconnection and heat sink. The study observed the double-side cooling configuration improved the thermal resistance of the package to be less than 0.1242° C./W, reduced the parasitic resistance from the package to 0.38 mΩ, and reduced power terminal parasitic inductance to 4.19 nH. The insulation capability is analyzed by simulation and partial discharge (PD) test at more than two times the rated voltage. FIG. 8A shows a photo of the fabricated device. FIG. 6B shows the experimental setup for the evaluation of the device. FIG. 8B-8G show simulated and measured characterization of the device.

### Results of the TO Double-Sided Cooling Package

Thermal Performance. FIG. 7A shows the simulation results for the thermal resistance characterization (θ_{JC}) of the device having an emitter frame that is employed for electrical connection and to remove heat. The module's junction-to-case thermal resistance (θJC) was analyzed by SolidWorks Flow Simulation. The study ran the simulation under a standard atmosphere with a 20° C. ambient temperature. FIG. 7A shows the model with the same structure as the fabricated package. The 20° C. constant temperature boundary condition was applied to both sides of the package thermal pad. The whole package is encapsulated in epoxy. The power device die was set as the heat source with 100 W heat generation. In FIG. 7A, the maximum junction temperature was observed to be 37.8° C. at the base region and 32° C. at the emitter region to provide a calculated junction-to-case thermal resistance of approximately 0.1775° C./W.

Parasitic parameter. FIG. 7B shows the simulated parasitic parameter for the device. The dynamic performance of the devices is highly dependent on the parasitic parameters of the package. The study used ANSYS Q3D Extractor to determine the parasitic parameters for analysis and optimization during the package design. In FIG. 7B, the parasitic inductance of the base to emitter was observed to be 4.19 nH at 100 kHz; the parasitic inductance of the power loop was 4.5 nH at 100 kHz; the parasitic resistance was 0.15 mΩ for the power loop at DC condition and increased to 0.7 mΩ at 200 KHz.

Isolation Design and PD Test. The study evaluated the complex interconnect inside the package to remove or reduce the electrical field crossing. The study used ANSYS Maxwell to analyze and optimize the 3D electrical distribution to improve the package isolation capability. To avoid the connector plate electric field crowding effect at the edge of the chip, all connectors were designed not to cross the chip edge. In FIG. 7C, the cross-view of electrical field distribution is shown at different positions of the package when 1600V is applied to E1 and E2. Because of the 3D stair copper structure, it was observed that even at an increased voltage of 1.6 kV, the highest electric field was less than 2×10⁶ V/m and was only excited at the surface of the chip. Multiple floating field ring edge terminations can be employed on the chip.

In addition, it was observed that the 3D stair structure of the exemplary device increased the creepage of the isolation region, which can minimize electric field crowding caused by the corner effect. To verify the package's isolation capability, a PCB dummy dies with the same thickness, size, and metal pad as real world four terminal power device dies are fabricated. The dummy chip was soldered into the package to test the insulation of the package. Tektronix 370A Curve Tracer measured the package's blocking character at room temperature. The leakage current for the package was observed to be 7.75 nA when applying 1600V between E1 and E2.

FIG. 6A shows the experimental setup for the evaluation of the device. The experimental setup was used to investigate the isolation behaviors of the package using a Partial Discharge (PD) test under PWM voltage stress. As shown in FIG. 6A, a ±5 kV GaN-based innovative high-frequency PWM wave PD tester was used [6]. FIG. 7D shows the measured test results.

In FIG. 7D, the results are shown with an expanded time scale highlighting rising edge waveforms. The DUTs were tested with 10 kHz PWM waveform output voltage in which the applied voltage was increased by 125V step increments to the partial discharge inception voltage (PDIV). PD signals were captured by both the HFCT and an antenna at a certain applied voltage level. The PDIV of the package from the E1 terminal to the E2 terminal was observed to reach 3500V in the air, which is around 3 times the voltage rating of the power device.

### Results of the TO Double-Sided Pressed-Pack Cooling Package

Thermal performance. FIG. 8B shows the simulation results for the thermal resistance characterization (θ_{JC}) of the device. The package's junction-to-case thermal resistance (θ_{JC}) was analyzed by SolidWorks Flow Simulation. The simulation was run under a standard atmosphere with a 20° C. ambient temperature. The model has the same structure and material as the fabricated package shown in FIG. 8A. The simulation employed a 20° C. constant temperature boundary condition on both sides of the package thermal pad and set the chip as a heat source with 100 W heat generation. In FIG. 8B, the maximum junction temperature was observed to be 32.47° C., corresponding to a calculated junction-to-case thermal resistance of approximately 0.1242° C./W.

Parasitic parameter. FIG. 8C shows the simulated parasitic parameter for the device. The dynamic performance of the devices is highly dependent on the parasitic parameters of the package. The study used ANSYS Q3D Extractor to determine the parasitic parameters for analysis and optimization during the package design. FIG. 8C shows the parasitic loop inductance and resistance simulation results over a pre-defined frequency range. In the simulation, the parasitic inductance from the base to the emitter was observed to be 4.19 nH at 100 kHz; the parasitic inductance from the Emitter1 to Emitter2 was 4.5 nH at 100 kHz; the parasitic resistance was 0.38 mΩ from Emitter1 to Emitter 2 at DC condition and increased to 0.92 mΩ at 200 kHz.

Isolation Design and PD Test. The study evaluated the complex interconnect inside the package to remove or reduce the electrical field crossing. The study used ANSYS Maxwell to analyze and optimize the 3D electrical distribution to improve the package isolation capability. To avoid the connector plate electric field crowding effect at the edge of the chip, all connectors were designed not to cross the chip edge. FIG. 8D shows a cross-view of the simulated electrical field distribution in the middle of the package at 1600V as applied to E1 and E2. The highest electric field was observed to be less than 6×10⁶ V/m and was only excited at the surface of the chip.

To verify the package isolation capability, a PCB-based dummy die with the same thickness, size, and metal pad as the actual chip was designed, fabricated, and soldered into the package. The study used Tektronix 370A Curve Tracer to measure the package's blocking characteristic at room temperature. The leakage current for the package is 4.45 nA when applying 1600V between E1 and E2.

FIG. 6B shows the experimental setup for the evaluation of the device. The experimental setup was used to investigate the isolation behaviors of the package under sinusoidal voltage stress using a Partial Discharge (PD) test. As shown in FIG. 6B, the experimental setup used a high-frequency current transformer (HFCT) to capture the PD impulse current. A C-L-3C filter was designed to remove the PD-like noise from the power supply. The experimental setup properly terminated all interconnections and conducted both AC and DC PD tests up to 30 kV with a background noise level of 5 pC [7′].

FIG. 8E shows the experimental results of the PD test at AC 60 Hz excitation. The measured partial discharge inception voltage (PDIV) for the package from the E1 terminal to the E2 terminal was measured to be around 1.83 k V_{RMS}/2.52 kV peak in air, which was acquired as an averaged value over multiple tests and over two times of the device rating. F

FIG. 8F shows the partial discharge results over a 5-minute span. The D pattern diagram at AC 60 Hz 2.52 kV peak shows that the partial discharge was smaller than 200 pC and only discharged occasionally after the voltage was increased to 2.52 kV peak.

FIG. 8G shows the measured package isolation characteristics of the device. To device was filled with isolation oil for the test to further optimize the package house. In FIG. 8B, the measured partial discharge inception voltage (PDIV) for the package from the E1 terminal to the E2 terminal was measured to be more than 5 kVRMS/7 kV peak. Based on this observation, it is expected that the package can operate at higher voltages.

### DISCUSSION

Emerging power devices such as the four-terminal power transistor [1], [2] is a double side double-patterned power device. However, the standard package, such as TO-247, is only suitable for single-side patterned power devices and the cooling is only from one side of the device. Hence, the current TO package is not suitable for this type of new device [3]. On the other hand, double-side cooling packages have been used in high-power semiconductor devices such as GTO and thyristor [4]. But there is very little effort like this in the TO package. Other reported double-side cooled packaging concepts are based on wire-bond technology and directed bonded copper (DBC) substrate. The extensive footprint of the DBC housing and wire bonds increases the parasitic inductance and decreases the thermomechanical reliability [5].

Considering all these factors, there is an urgent need to develop a new generation of TO packaging technology that can fully enable the potential of double-sided patterned power devices. Therefore, a novel ultra-compact wire bonding less TO double-side cooling package with 3D copper lead frames is proposed and developed in this paper to achieve low thermal resistance, good electrical performance, and low manufacturing cost. The simulation and test results are presented to verify the advantages of the new package.

Design and Characterization of a Double-side Cooled Press-Pack Packaging Structure. Double-side patterned power devices such as the recently introduced four-terminal power transistor [1′], [2′] require special packaging considerations. Standard single-side wire bond packages such as TO-247 are not suitable for double-side patterned power devices. TO-247 is also single side cooled device packaging hence has limited thermal performance. Some reported double-side packages are still based on traditional wire-bond technology on directed bonded copper (DBC) substrates. The extensive footprint of the DBC housing and wire bonds increases the parasitic inductance and decreases the thermomechanical reliability [5′]. On the other hand, double-side cooling press-pack packages with excellent thermal performance have been used widely in high-power semiconductor devices for many decades [3′], [4′]. However, no such effort is widely reported for discrete power devices. So a pressure-based assembly is another suitable direction to consider for double-side patterned power devices. In a press-pack TO package, joints are formed by pressure-based bonding, which is simpler and more reliable compared to other connection methods, such as wire bonding, soldering, and sintering. [6]

There is thus a need to develop a new generation of TO packaging technology that can fully enable the potential of double-sided patterned power devices. The exemplary TO and TO pressed pack devices described herein can address these technical challenges while providing low thermal resistance characteristics and low manufacturability.

### CONCLUSION

Throughout the description and claims of this specification, the word “comprise” and other forms of the word, such as “comprising” and “comprises,” means including but not limited to, and are not intended to exclude, for example, other additives, segments, integers, or steps. Furthermore, it is to be understood that the terms comprise, comprising, and comprises as they relate to various aspects, elements, and features of the disclosed invention also include the more limited aspects of “consisting essentially of” and “consisting of.”

As used herein, the singular forms “a,” “an,” and “the” include plural referents unless the context clearly dictates otherwise. Thus, for example, reference to a “polymer” includes aspects having two or more such polymers unless the context clearly indicates otherwise.

Ranges can be expressed herein as from “about” one particular value and/or to “about” another particular value. When such a range is expressed, another aspect includes from the one particular value and/or to the other particular value. Similarly, when values are expressed as approximations, by use of the antecedent “about,” it will be understood that the particular value forms another aspect. It should be further understood that the endpoints of each of the ranges are significant both in relation to the other endpoint, and independently of the other endpoint.

As used herein, the terms “optional” or “optionally” mean that the subsequently described event or circumstance may or may not occur, and that the description includes instances where said event or circumstance occurs and instances where it does not.

For the terms “for example” and “such as,” and grammatical equivalences thereof, the phrase “and without limitation” is understood to follow unless explicitly stated otherwise.

The following patents, applications and publications as listed below and throughout this document are hereby incorporated by reference in their entirety herein.

### REFERENCE LIST

[1] A. Mojab, J. Bu, J. Knapp, A. Sattar and D. Brdar, “Operation and Characterization of Low-Loss Bidirectional Bipolar Junction TRANsistor (B-TRAN™),” 2022 IEEE Applied Power Electronics Conference and Exposition (APEC), Houston, TX, USA, 2022, pp. 205-209, doi: 10.1109/APEC43599.2022.9773733
[2] M. Dong, R. Yu, Y. Jiang, J. Bu, J. Knapp and D. Brdar, “B-TRAN™ Optimization and Performance Characterization,” 2023 IEEE Applied Power Electronics Conference and Exposition (APEC), Orlando, FL, USA, 2023, pp. 1835-1839, doi: 10.1109/APEC43580.2023.10131453
[3] Y. Yang, L. Dorn-Gomba, R. Rodriguez, C. Mak and A. Emadi, “Automotive Power Module Packaging: Current Status and Future Trends,” in IEEE Access, vol. 8, pp. 160126-160144, 2020, doi: 10.1109/ACCESS.2020.3019775.K. Elissa, “Title of paper if known,” unpublished.
[4] M. Liu, A. Coppola, M. Alvi and M. Anwar, “Comprehensive Review and State of Development of Double-Sided Cooled Package Technology for Automotive Power Modules,” in IEEE Open Journal of Power Electronics, vol. 3, pp. 271-289, 2022, doi: 10.1109/OJPEL.2022.3166684.
[5] L. Wang, W. Wang, R. J. E. Hueting, G. Rietveld and J. A. Ferreira, “Review of Topside Interconnections for Wide Bandgap Power Semiconductor Packaging,” in IEEE Transactions on Power Electronics, vol. 38, no. 1, pp. 472-490, January 2023, doi: 10.1109/TPEL.2022.3200469.
[6] Haotao Ke, Yifan Jiang, Adam J. Morgan, Douglas C. Hopkins; Investigation of Package Effects on the Edge Termination E-Field for HV WBG Power Semiconductors. International Symposium on Microelectronics 1 Oct. 2017; 2017 (1): 000224-000230. doi: https://doi.org/10.4071/isom-2017-WA32_092
[7] Z. Guo, T. Chen, R. Yu and A. Q. Huang, “GaN-based+5 kV/100 kHz PWM Generator for Advanced Partial Discharge Characterization,” 2021 IEEE Energy Conversion Congress and Exposition (ECCE), Vancouver, BC, Canada, 2021, pp. 5894-5898, doi: 10.1109/ECCE47101.2021.9595274

### REFERENCE LIST #2

[1′] A. Mojab, J. Bu, J. Knapp, A. Sattar and D. Brdar, “Operation and Characterization of Low-Loss Bidirectional Bipolar Junction TRANsistor (B-TRAN™),” 2022 IEEE Applied Power Electronics Conference and Exposition (APEC), Houston, TX, USA, 2022, pp. 205-209, doi: 10.1109/APEC43599.2022.9773733
[2′] M. Dong, R. Yu, Y. Jiang, J. Bu, J. Knapp and D. Brdar, “B-TRAN™ Optimization and Performance Characterization,” 2023 IEEE Applied Power Electronics Conference and Exposition (APEC), Orlando, FL, USA, 2023, pp. 1835-1839, doi: 10.1109/APEC43580.2023.10131453.
[3′] Y. Yang, L. Dorn-Gomba, R. Rodriguez, C. Mak and A. Emadi, “Automotive Power Module Packaging: Current Status and Future Trends,” in IEEE Access, vol. 8, pp. 160126-160144, 2020, doi: 10.1109/ACCESS.2020.3019775.K. Elissa, “Title of paper if known,” unpublished.
[4′] M. Liu, A. Coppola, M. Alvi and M. Anwar, “Comprehensive Review and State of Development of Double-Sided Cooled Package Technology for Automotive Power Modules,” in IEEE Open Journal of Power Electronics, vol. 3, pp. 271-289, 2022, doi: 10.1109/OJPEL.2022.3166684.
[5′] L. Wang, W. Wang, R. J. E. Hueting, G. Rietveld and J. A. Ferreira, “Review of Topside Interconnections for Wide Bandgap Power Semiconductor Packaging,” in IEEE Transactions on Power Electronics, vol. 38, no. 1, pp. 472-490, January 2023, doi: 10.1109/TPEL.2022.3200469.
[6′] E. Deng, Z. Zhao, Z. Lin, R. Han and Y. Huang, “Influence of Temperature on the Pressure Distribution Within Press Pack IGBTs,” in IEEE Transactions on Power Electronics, vol. 33, no. 7, pp. 6048-659 July 2018, doi: 10.1109/TPEL.2017.2749521.M. Young, The Technical Writer's Handbook. Mill Valley, CA: University Science, 1989.
[7′] Feng X, Xiong Q, Gattozzi A, Montanari GC, Seri P, Hebner R. Cable commissioning and diagnostic tests: The effect of voltage supply frequency on partial discharge behavior. In 2018 12th International Conference on the Properties and Applications of Dielectric Materials (ICPADM) 2018 May 20 (pp. 373-376). IEEE.

What is claimed is:

1. A switch package for a semiconductor device, the package comprising:
a semiconductor die having a first side and a second side, each having electrical terminals and contact metal pads formed thereon; and
a first and second cooling plate members disposed on a side of the die, the first cooling plate member having (i) a first pin structure extending in a direction parallel to the first side of the die to form a first pin for the switch package and (ii) one or more pillar or spacer structures extending in a direction perpendicular to the first side to electrically and thermally contact corresponding one or more electric pads for a first electrical terminal located on said first side; and
at least one cooling frame member, including a first cooling frame member, for a double-sided cooling package, the first cooling frame member being disposed, in electrical isolation, either proximal to the one or more pillar or spacer structures or in a channel formed between pillar structures of the one or more pillar structures, the first frame member having (i) a second pin structure extending in the direction parallel to the first side to form a second pin for the switch package and (ii) one or more pillar or spacer structures extending in a direction perpendicular to the first side to electrically and thermally contact one or more electric pads for a second circuit terminal located on said first side.

2. The switch package device of claim 1, wherein the at least one cooling frame member further includes:
a second cooling frame member, for the double-sided cooling package, wherein the second cooling frame member is disposed proximal to the pillar or spacer structures of the first cooling plate member, the first frame member having (i) a pin structure extending in the direction parallel to a die surface of the die to form a third pin for the switch package and (ii) a pillar or spacer structure extending in a direction perpendicular to one of the die surface to electrically and thermally contact one or more electric pads on a side of the die.

3. The switch package device of claim 1, wherein the second cooling plate member includes (i) a pin structure extending in a direction parallel to the second side of the die to form a fourth pin for the switch package and (ii) one or more pillar or spacer structures extending in a direction perpendicular to the second side to electrically and thermally contact corresponding one or more electric pads for a second circuit terminal located on said second side.

4. The switch package device of claim 1, wherein the semiconductor die comprises a power semiconductor device having two, three, four, or more terminals, and these terminals are located on two sides of the die.

5. The switch package device of claim 1, wherein the semiconductor die comprises one or more bipolar junction transistors or field-effect transistors on each of the first side and the second side.

6. The switch package device of claim 1, wherein the first pin and the second pin are aligned along a same plane.

7. The switch package device of claim 1, wherein the first pin and the second pin include an offset to be aligned along a same plane co-located with a plane of the electrical patterns of the first side, the second side, or a plane located therebetween.

8. The switch package device of claim 1, wherein an active space of the device is encapsulated by epoxy or dielectric material.

9. The switch package device of claim 1, wherein the semiconductor die, the first and second cooling plate members, and the at least one cooling frame member collectively form a TO-packaged device.

10. The switch package device of claim 1, wherein the semiconductor die, the first and second cooling plate members, and the at least one cooling frame member collectively form a pressed pack package device, wherein the first and second cooling plate members are externally located to components of the device and includes mounting holes to receive mounting connectors and pressure.

11. The switch package device of claim 1, wherein the one or more pillar or spacer structures of the first cooling plate member include one or more Molybdenum spacers.

12. The switch package device of claim 1, wherein the package device is wire-bondless and solderless.

13. The switch package device of claim 1, wherein the first cooling frame member has a U-shape member to electrically contact two or more pads of the electrical terminals and contact metal pads of the die.

14. The switch package of claim 1, wherein the first and second cooling plate members each has a conductive substrate having an area at least that of the respective side of the semiconductor die, the first and second cooling plate members each being disposed in parallel and facing the respective side to span over the first pad, the second pad, and a third pad.

15. The switch package of claim 14, wherein the first cooling frame member has a conductive substrate disposed in the channel and extending in the first direction to form a third external pin to the semiconductor die, the first cooling frame member, including a protrusion that each extends in the second direction, in isolation to the first and second pillar of the first cooling plate member, to form a fifth pillar to contact the third pad.

16. A switch package device for semiconductor devices comprising:
two or more semiconductor dies, including a first semiconductor die, each of the two or more semiconductor dies having a first side and a second side, each side having electrical patterns formed thereon; and
the first semiconductor die comprising:
a first and second cooling plate members for a double-sided cooling package, each die plate member disposed on a side of the die, the first cooling plate member having (i) a first pin structure extending in a direction parallel to the first side of the die to form a first pin for the switch package and (ii) one or more pillar or spacer structures extending in a direction perpendicular to the first side to electrically and thermally contact corresponding one or more electric pads for a first circuit terminal located on said first side; and
at least one cooling frame member, including a first cooling frame member, for the double-sided cooling package, the first cooling frame member being disposed, in electrical isolation, either proximal to the one or more pillar or spacer structures or in a channel formed between pillar structures of the one or more pillar structures, the first frame member having (i) a second pin structure extending in the direction parallel to the first side to form a second pin for the switch package and (ii) one or more pillar or spacer structures extending in a direction perpendicular to the first side to electrically and thermally contact one or more electric pads for a second circuit terminal located on said first side.

17. The switch package device of claim 16,
wherein the second semiconductor die comprises:
a first and second cooling plate members for a double-sided cooling package, each die plate member disposed on a side of the die, the first cooling plate member having (i) a first pin structure extending in a direction parallel to the first side of the die to form a first pin for the switch package and (ii) one or more pillar or spacer structures extending in a direction perpendicular to the first side to electrically and thermally contact corresponding one or more electric pads for a first circuit terminal located on said first side; and
at least one cooling frame member, including a first cooling frame member, for the double-sided cooling package, the first cooling frame member being disposed, in electrical isolation, either proximal to the one or more pillar or spacer structures or in a channel formed between pillar structures of the one or more pillar structures, the first frame member having (i) a second pin structure extending in the direction parallel to the first side to form a second pin for the switch package and (ii) one or more pillar or spacer structures extending in a direction perpendicular to the first side to electrically and thermally contact one or more electric pads for a second circuit terminal located on said first side.

18. The switch package device of claim 16, wherein the switch package device includes an array of four-terminal power transistor dies.

19. The switch package device of claim 16, wherein the first semiconductor die, the second semiconductor die, the first and second cooling plate members of the first semiconductor die, the first and second cooling plate members of the second semiconductor die, and the at least one cooling frame member, collectively form a TO-packaged device.

20. The switch package device of claim 16, wherein the first semiconductor die, the second semiconductor die, the first and second cooling plate members of the first semiconductor die, the first and second cooling plate members of the second semiconductor die, and the at least one cooling frame member, collectively form a pressed-pack package device.
